(19) United States
(12) Patent Application Publication
(10) Pub. No.: US 2025/0309174 A1
(43) Pub. Date: Oct. 2, 2025

(54) ELECTRONIC DEVICE AND METHOD OF MANUFACTURING THE SAME

(71) Applicant: Innolux Corporation, Miaoli County (TW)

(72) Inventors: Wei-Yuan Cheng, Miaoli County (TW); Ker-Yih Kao, Miaoli County (TW); Ju-Li Wang, Miaoli County (TW)

(73) Assignee: Innolux Corporation, Miaoli County (TW)

(21) Appl. No.: 19/073,053

(22) Filed: Mar. 7, 2025

Related U.S. Application Data
(60) Provisional application No. 63/572,893, filed on Apr. 1, 2024.

(30) Foreign Application Priority Data
Sep. 19, 2024 (CN) 202411310130.5

(51) Int. Cl. H01L 23/00; H01L 21/56; H01L 23/31; H01L 25/07

(52) U.S. Cl. CPC H01L 24/24; H01L 21/561; H01L 23/3185; H01L 24/19; H01L 24/32; H01L 24/73; H01L 25/072; H01L 2224/19; H01L 2224/2405; H01L 2224/24137; H01L 2224/32245; H01L 2224/73267

(57) ABSTRACT

The present disclosure provides an electronic device and a method of manufacturing the same. The electronic device includes at least one first electronic unit, a molding layer surrounding the at least one first electronic unit, a circuit structure electrically connected to the at least one first electronic unit, a conductive layer in which the circuit structure and the conductive layer are corresponded to the opposite sides of the molding layer, and a connection element disposed between the circuit structure and the conductive layer. The molding layer surrounds the connection element and includes a recess.

### CROSS-REFERENCE TO RELATED APPLICATION

This application claims the priority benefit of U.S. provisional application Ser. No. 63/572,893, filed on Apr. 1, 2024, and China application serial no. 202411310130.5, filed on Sep. 19, 2024. The entirety of each of the above-mentioned patent applications is hereby incorporated by reference herein and made a part of this specification.

### BACKGROUND

### Technical Field

The present disclosure relates to an electronic device and a method of manufacturing the same, and particularly relates to an electronic device with good reliability.

### Description of Related Art

In general, after an electronic element is bonded to a substrate, a gap between the electronic element and the substrate is filled with an underfill by performing an underfill process, so that connection structures such as pads and solder balls between the electronic element and the substrate are encapsulated by the underfill. As such, the electrical connection between the electronic element and the substrate can be ensured and the relative position between the electronic element and the substrate can be fixed. However, as the sizes of the electronic devices continue to develop towards light, thin, short, and small aspects, and the user's requirements to the performances of the electronic devices continue to increase, the existing structural designs and/or manufacturing processes may be difficult to meet the current or future requirements for the reliability or quality of the electronic devices.

### SUMMARY

The present disclosure provides an electronic device and a manufacturing method of the electronic device in which the encapsulating layer is designed to include a recess to increase the contact area between the underfill and the encapsulating layer, so that the reliability or the quality of the electronic device can be enhanced.

According to an embodiment of the present disclosure, the electronic device includes at least one first electronic unit, an encapsulating layer, a circuit structure, a conductor layer, and a connection element. The encapsulating layer surrounds the at least one first electronic unit. The circuit structure is electrically connected to the at least one first electronic unit. The circuit structure and the conductor layer are corresponded to opposite sides of the encapsulating layer. The connection element is disposed between the circuit structure and the conductor layer, wherein the encapsulating layer surrounds the connection element and includes a recess.

According to an embodiment of the present disclosure, the manufacturing method of the electronic device includes following steps. At least one electronic unit is provided. An encapsulating layer surrounding the at least one electronic unit is provided. A circuit structure electrically connected to the at least one electronic unit is provided. A conductor layer is provided, wherein the circuit structure and the conductor layer are corresponded to opposite sides of the encapsulating layer. A connection element disposed between the circuit structure and the conductor layer is provided. A recess is formed in the encapsulating layer, wherein the recess is formed between neighboring two of the at least one electronic unit.

Based on the above, in the embodiment of the present disclosure, the encapsulating layer in the electronic device is designed to include a recess to improve the contact area between the underfill and the encapsulating layer, and thus the reliability or the quality of the electronic device can be enhanced.

To make the features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are cross-sectional schematic views of a manufacturing method of an electronic device according to the first embodiment of the present disclosure.

FIG. 1F is an enlarged schematic view of a region R1 in FIG. 1E according to an embodiment.

FIG. 1G is a top view schematic diagram of an electronic element in FIG. 1E according to an embodiment.

FIG. 2A is a cross-sectional schematic view of an electronic device according to an embodiment of the present disclosure.

FIG. 2B is a cross-sectional schematic view of an electronic device according to another embodiment of the present disclosure.

FIG. 3A and FIG. 3B are cross-sectional schematic views of a manufacturing method of an electronic device according to the second embodiment of the present disclosure.

FIG. 4A and FIG. 4B are cross-sectional schematic views of a manufacturing method of an electronic device according to the third embodiment of the present disclosure.

FIG. 5A to FIG. 5D are cross-sectional schematic views of a manufacturing method of an electronic device according to the fourth embodiment of the present disclosure.

FIG. 6 is a cross-sectional schematic view of an electronic device according to yet another embodiment of the present disclosure.

FIG. 7A to FIG. 7D are cross-sectional schematic views of a manufacturing method of an electronic device according to the fifth embodiment of the present disclosure.

FIG. 8A is a cross-sectional schematic view of an electronic device according to still another embodiment of the present disclosure.

FIG. 8B is a cross-sectional schematic view of an electronic device according to still yet another embodiment of the present disclosure.

FIG. 9A to FIG. 9E are cross-sectional schematic views of a manufacturing method of an electronic device according to the sixth embodiment of the present disclosure.

FIG. 10 is a cross-sectional schematic view of an electronic device according to an embodiment of the present disclosure.

FIG. 11 is a cross-sectional schematic view of an electronic device according to an embodiment of the present disclosure.

### DESCRIPTION OF THE EMBODIMENTS

The disclosure can be understood with reference to the following detailed description in conjunction with the accompanying drawings. It should be noted that, for ease of understanding by readers and for the concision of the illustration, a plurality of drawings in the disclosure only depict a part of the package structure, and certain elements in the drawings are not drawn according to actual scale. In addition, the number and size of each element in the drawings are for illustration only, and are not intended to limit the scope of the disclosure. For example, the relative sizes, thicknesses and positions of various layers, regions and/or structures may be reduced or enlarged for clarity.

Certain terms may be used throughout the disclosure and the claims to refer to specific elements. Those skilled in the art will understand that electronic device manufacturers may refer to the same elements by different names. The disclosure does not intend to distinguish between elements that have the same function but have different names. In the following description and claims, the words including “having” and “including” are open-ended words, and thus should be interpreted as meaning “including but not limited to.”

Directional terms mentioned herein, such as “up,” “down,” “front,” “rear,” “left,” “right,” and the like refer only to the directions of the drawings. Accordingly, the directional terms used are for illustration, and are not intended to limit the disclosure. It should be understood that when an element or film layer is referred to as being “disposed on” or “connected to” another element or film layer, the element or the film layer may be directly on or connected to the another element or film layer, or intervening elements or film layers may also be present in between (non-direct circumstances). In contrast, when an element or film layer is referred to as being “directly on” or “directly connected to” another element or film layer, no intervening elements or film layers are present in between. In addition, when the element or film layer is referred to as overlapping another element, the element or film layer at least partially overlaps another element or film layer.

In the text, the terms “about,” “approximately,” “essentially,” or “substantially” usually implies that a value is within 10% of a given value or range, or within 5%, 3%, 2%, 1%, or 0.5% of a given value or range. In addition, the description “a given range from a first value to a second value” or “a given range between a first value and a second value” implies that the given range includes the first value, the second value, and other values in between.

In some embodiments of the disclosure, terms related to bonding and connection, such as “connection,” “interconnection,” and the like, unless otherwise specified, may mean that two structures are in direct contact, or may also mean that two structures are not in direct contact, in which there are other structures provided between these two structures. The terms related to bonding and connection may also include the case where both structures are movable, or both structures are fixed. Furthermore, the terms “electrically connected” or “coupled” includes any direct and indirect means of electrical connection.

In the embodiments provided later, the same or similar reference numerals are used to refer to the same or similar elements, and the descriptions will not be repeated. In addition, as long as the features of the various embodiments do not depart from or conflict with the spirit of the disclosure, the embodiments may be mixed and matched as desired. It is intended that the disclosure covers modifications and variations provided that they fall within the scope of the following claims and their equivalents. That is, in the following embodiments, technical features in several different embodiments may be replaced, reorganized, and mixed to complete other embodiments without departing from the spirit of the disclosure. Moreover, the terms such as “first” and “second” mentioned in the specification or the claims are only used to name different elements or to distinguish different embodiments or scopes, and are not intended to limit the upper or lower limit of the number of the elements, nor are they intended to limit the manufacturing order or disposition order of the elements.

In some embodiments of this disclosure, the thickness, length, and width may be obtained through a measurement using an optical microscope (OM). The thickness or the width may be obtained by measuring from a cross-sectional image in an electron microscope, but is not limited thereto. A surface roughness may be obtained by observing the surface undulations at an appropriate and consistent magnification through the electron microscope such as a scanning electron microscope (SEM) or a transmission electron microscope (TEM) and comparing the surface undulations per unit length (e.g., 10 μm). The appropriate magnification refers to a magnification that a roughness or an average roughness of at least one surface with at least 10 undulate peaks is observed in the field of view. Each of layers shown in the accompanying drawings of this disclosure may all have rough surfaces. It is worth noting that the rough surfaces of the aforementioned layers may refer to the high and low undulations presented in the cross-sectional view when observing the surfaces of each layer through the electron microscope.

The electronic device of this disclosure may include an antenna (e.g., liquid crystal antenna) function, a display function, a light-emitting function, a sensing function, a touch function, a tiled function, other suitable functions, or combinations of the above functions, but is not limited thereto. The electronic device includes a rollable electronic device or a flexible electronic device, but is not limited thereto. The display device may include, for example, a liquid crystal, a light emitting diode (LED), a quantum dot (QD), a fluorescence, a phosphor, other suitable materials or combinations thereof. The light emitting diode may include, for example, an organic light emitting diode (OLED), a micro-LED, a mini-LED or a quantum dot light emitting diode (QLED, QDLED), but is not limited thereto. According to some embodiments, the electronic device may include a panel and/or a backlight module, and the panel may include a liquid crystal panel or other self-emitting panels, but is not limited thereto. A tiled device may be, for example, a display tiled device or an antenna tiled device, but is not limited thereto. It should be noted that the electronic device may be any arrangement and combination of the aforementioned, but is not limited thereto.

The exemplary embodiments of this disclosure are described in the following for example, and the same reference numerals used in the figures and descriptions are represented to the same or similar portions.

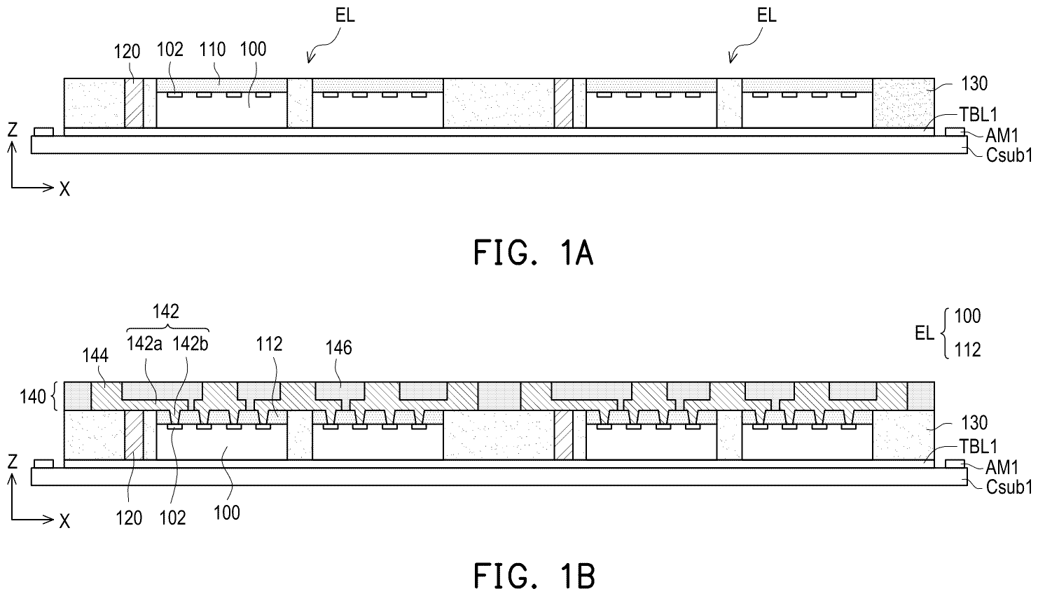

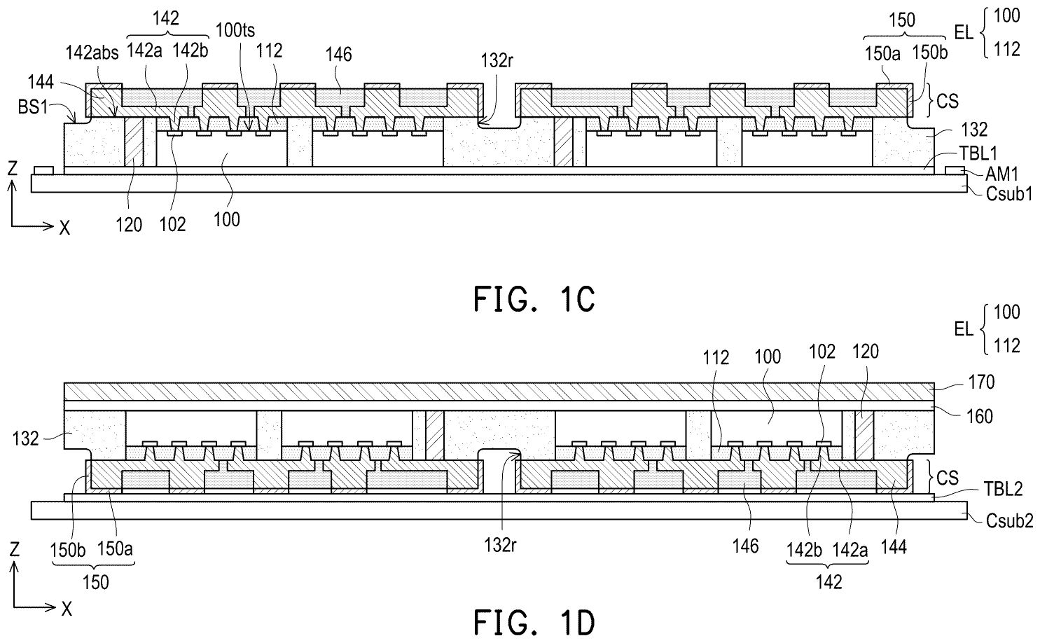

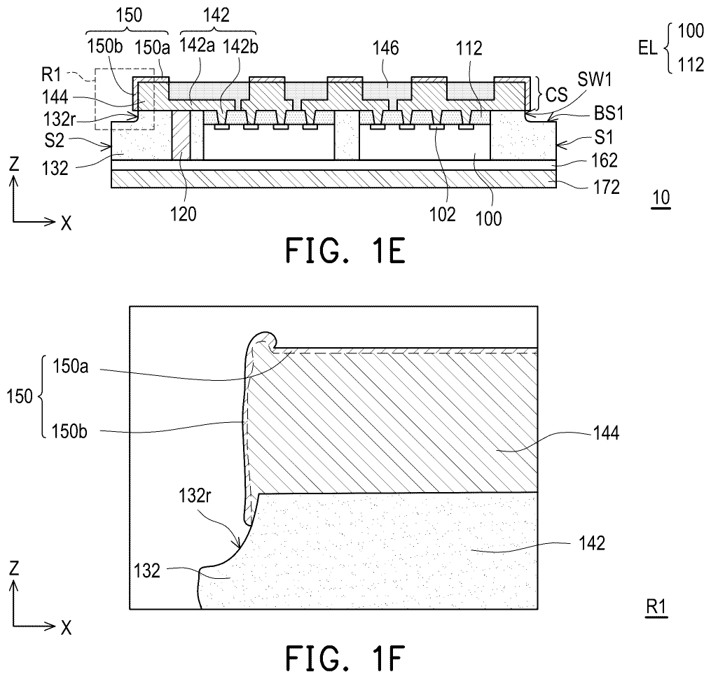

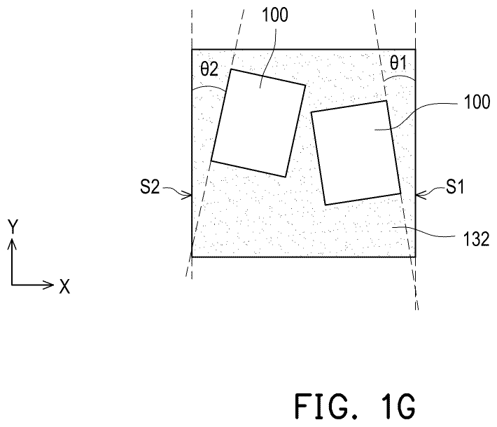

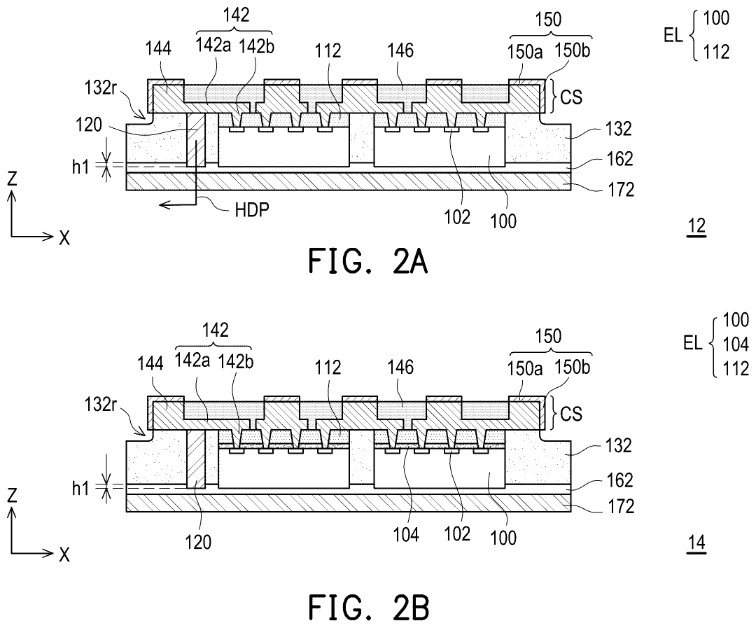

FIG. 1A to FIG. 1E are cross-sectional schematic views of a manufacturing method of an electronic device according to the first embodiment of the present disclosure. FIG. 1F is an enlarged schematic view of a region R1 in FIG. 1E according to an embodiment. FIG. 1G is a top view schematic diagram of an electronic element in FIG. 1E according to an embodiment. FIG. 2A is a cross-sectional schematic view of an electronic device according to an embodiment of the present disclosure. FIG. 2B is a cross-sectional schematic view of an electronic device according to another embodiment of the present disclosure. For the sake of convenience in explanation, FIG. 1G omits other components except for the electronic element 100 and the encapsulating layer 132.

In some embodiments, the manufacturing method of the electronic device (such as the electronic device 10 shown in FIG. 1E) may include the following steps.

First, referring to FIG. 1A, a plurality of electronic units EL are provided. Each electronic unit EL may include an electronic element 100 and an insulation layer 110 disposed on the electronic element 100. FIG. 1A illustrates, as an exemplary embodiment, that the amount of the electronic element 100 included in each electronic unit EL is 2, but the amount of the electronic element 100 is not limited to the amount of the electronic element 100 shown in FIG. 1A. The electronic element 100 may include a chip (e.g., a known good die, KGD), a diode, an antenna unit, a sensor, a structure related to a semiconductor process, or a structure related to the semiconductor process disposed on a substrate (e.g., a polyimide substrate, a glass substrate, a silicon substrate or a substrate made of other suitable materials). The electronic element 100 may include a conductive pad 102, wherein the conductive pad 102 may be located on a side (e.g., a front side) of the electronic element 100. The conductive pad 102 of the electronic element 100 may be electrically connected to other conductive elements. In this embodiment, the amount of the conductive pads 102 of different electronic elements 100 may be the same as or different from each other. According to some embodiments, the sizes of the conductive pads 102 of different electronic elements 100 may be the same as or different from each other. The conductive pad 102 may include any suitable conductive material, for example, copper (Cu), aluminum (Al), nickel (Ni), molybdenum (Mo), titanium (Ti), alloys or combinations of the above materials, or other suitable materials, but is not limited thereto. The insulation layer 110 may include any suitable insulating material, for example, the insulation layer 110 may include polybenzoxazole (PBO), polyimide (e.g., photosensitive polyimide (PSPI)), benzocyclobutene (BCB), Ajinomoto Build-up Film (ABF), silicon oxide (SiOx), silicon nitride (SiNx), silicon oxynitride (SiOxNy) or other suitable insulating materials or combinations thereof, but is not limited thereto.

In some embodiments, the electronic units EL may be provided on a carrier substrate Csub1 in an array arrangement. According to some embodiments, elements formed on the carrier substrate Csub1 may be removed from the carrier substrate Csub1, wherein the carrier substrate Csub1 may be reused in the manufacturing process of the electronic device, but is not limited thereto. The material of the carrier substrate Csub1 may include quartz, glass, stainless steel, sapphire, other suitable materials or combinations of the above, but is not limited thereto. In some embodiments, the electronic element 100 may be fixed on the carrier substrate Csub1 through a bonding layer TBL1. In some embodiments, the bonding layer TBL1 may be a temporary bonding layer, which may include a thermal-type or an optical-type release material having adhesiveness, so that working units, elements or film layers subsequently formed thereon can be temporarily adhered to the bonding layer TBL1. In other words, the bonding layer TBL1 may be of benefit of removing the working units, the elements or the film layers subsequently formed thereon from the carrier substrate Csub1. In the case where the thermal-type release material is used to form the bonding layer TBL1, the thermal-type release material loses its adhesiveness when the heat is performed on the thermal-type release material, so that the elements or the film layers formed thereon may be peeled off from the bonding layer TBL1. For example, the bonding layer TBL1 may be a thermal release tape (HRT) or a light-to-heat-conversion (LTHC) release coating. In the case where the optical-type release material is used to form the bonding layer TBL1, the optical-type release material loses its adhesiveness when the optical-type release material is exposed to the radiation such as an ultra-violet light (UV light), so that the elements or the film layers formed thereon may be peeled off from the bonding layer TBL1. For example, the bonding layer TBL1 may be a UV paste.

In some embodiments, alignment marks AM1 may be provided on the carrier substrate Csub1, so that the electronic units EL may be provided on the carrier substrate Csub1 in a desired arrangement. In some embodiments, the shape of the alignment marks AM1 may be, for example, a cross-shape, a circular shape, a triangular shape, a rectangular shape, or other suitable geometric shapes, but is not limited thereto.

Next, connection elements 120 are provided on the bonding layer TBL1 at sides of the electronic units EL. In some embodiments, the materials of the connection elements 120 may include silicon, metal, or combinations thereof. For example, the connection elements 120 may include a silicon bulk, a metal bulk, or a bulk with a composite material.

Then, an encapsulating layer 130 surrounding the plurality of electronic units EL and connection elements 120 are provided. In some embodiments, the encapsulating layer 130 may surround the electronic elements 100 and the insulation layer 110 provided on the electronic elements 100. In this embodiment, the description of “one element surrounding another element” may refer to the element at least partially contacting the side surface of another element in a cross-sectional view of the electronic unit EL. For example, as illustrated in FIG. 1A, the encapsulating layer 130 may contact the side surfaces of the electronic elements 100 and the insulation layer 110. The encapsulating layer 130 may prevent the electronic elements 100 from being affected by the external moisture, thereby improving the reliability of the electronic units EL. The encapsulating layer 130 may include any suitable organic or inorganic material, for example, epoxy molding compound (EMC), silicon oxide (SiOx), silicon nitride (SiNx), silicon oxynitride (SiOxNy), but is not limited thereto. In some other embodiments, the description of “one element surrounding another element” may refer to the element being adjacent to the side surface of another element in a cross-sectional view of the electronic unit EL, but the present disclosure is not limited thereto. In some embodiments, the encapsulating layer 130 may be formed, for example, by the following steps. First, an encapsulating material layer covering a plurality of electronic units EL and connection elements 120 is formed on the bonding layer TBL1. Then, a portion of the encapsulating material layer above the top surfaces of the electronic units EL and connection elements 120 is removed through, for example, grinding, to form the encapsulating layer 130. In this embodiment, the top surface of the encapsulating layer 130 may be formed to be coplanar with the top surfaces of the connection elements 120 and electronic units EL.

After that, referring to FIG. 1A and FIG. 1B, a circuit structure 140 electrically connected to the electronic units EL is provided. In this embodiment, the circuit structure 140 may be disposed on the top surface of the encapsulating layer 130. The circuit structure 140 may include any suitable structure formed by stacking insulation layers and conductive layers, where the stacking direction of the insulation layers and conductive layers may be parallel to the normal direction of the electronic units EL (e.g., direction Z). For example, the circuit structure 140 may include a conductive layer 142, a conductive layer 144 disposed on the conductive layer 142, and an insulation layer 146 covering the conductive layer 142 and surrounding the conductive layer 144. In some embodiments, the conductive layer 142 may include conductive wires 142a extending horizontally and conductive vias 142b extending vertically and passing through the insulation layer 110 and electrically connected to the conductive pads 102. In some embodiments, in the case where the insulation layer 110 is an Ajinomoto build-up film (ABF), a laser drilling process may be performed on the insulation layer 110 to form via holes in the insulation layer 112 for the conductive vias 142b. In some alternative embodiments, the circuit structure 140 may include a structure formed by stacking more conductive layers and insulation layers. In this embodiment, the conductive layer 142 in the circuit structure 140 may be directly disposed on the top surface of the encapsulating layer 130, but is not limited thereto. The conductive layers (e.g., conductive layers 142 and 144) in the circuit structure 140 may include any suitable conductive material, for example, copper, titanium, nickel, gallium (Ga), ruthenium (Ru), tantalum (Ta), combinations or alloys of the above materials, but are not limited thereto. The conductive layer in the circuit structure 140 may be a single-layer or a multi-layer stacked structure, and the conductive layer may include a seed layer, which may improve the bonding strength between the conductive layer and the insulation layer, but is not limited thereto. The insulation layer (e.g., insulation layer 146) in the circuit structure 140 may include any suitable insulation material, for example, build-up layer, polyimide, resin (e.g., epoxy resin), silicon oxide, silicon nitride, solder resist, or combinations thereof, but is not limited thereto. In some embodiments, the insulation material above the conductive layer 144 may be removed through a grinding process, a photolithography etching, or other suitable methods to form the insulation layer 146 and to expose the top surface of the conductive layer 144. In some embodiments, the material of the connection elements 120 may be the same as the material of the conductive layer in the circuit structure 140.

In some embodiments, the circuit structure 140 may also be referred to as a redistribution structure. The redistribution structure may be electrically connected to chips or other electronic elements through solder balls or other bonding elements. The redistribution structure may include at least one insulation layer and at least one conductive layer alternately stacked along direction Z. The circuit may be redistributed and/or the fan-out or fan-in area may be enhanced through the at least one insulation layer and the at least one conductive layer, or different electronic elements may be electrically connected to each other through the redistribution structure. For example, the pitch between two adjacent contact pads at the end of the redistribution structure contacting the electronic element may be smaller than or equal to the pitch between two adjacent contact pads at the end of the redistribution structure away from the electronic element. Therefore, the redistribution structure may adjust the circuit fan-out condition or electrically connect a circuit structure or an electronic element with a first pitch to a circuit structure or an electronic element with a second pitch, but is not limited thereto. The method of forming the redistribution structure may include using a photolithography etching process, a surface treatment process, a laser process, an electroplating process, an electroless plating process, a deposition process, an atomic layer deposition process, or other processes to form the at least one insulation layer and the at least one conductive layer. The surface treatment process includes roughening or activating the surface of the dielectric layer or the conductive layer to enhance its ability adhesion. For example, the bonding strength between the dielectric layer or the conductive layer with the film layers subsequent formed thereon may be enhanced by increasing the surface roughness of the dielectric layer or the conductive layer.

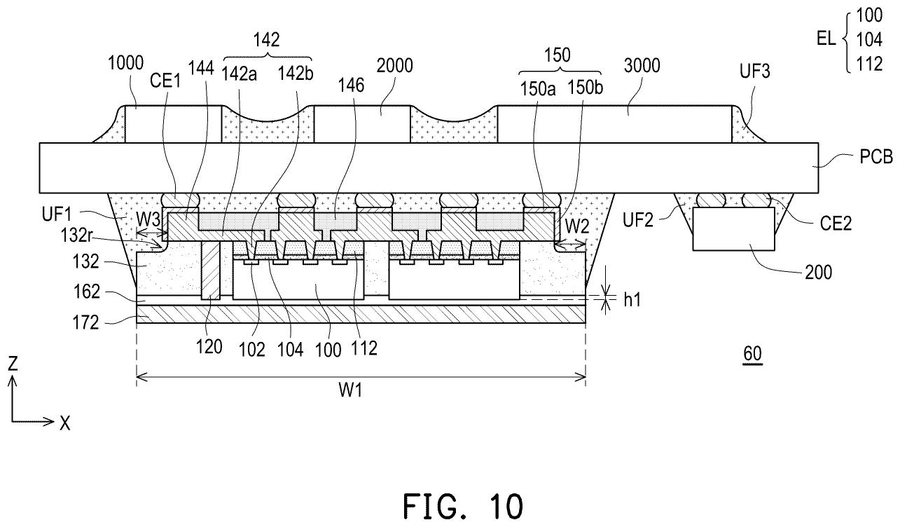

Thereafter, referring to FIG. 1B and FIG. 1C, portions of the insulation layer 146 and portions of the encapsulating layer 130 under the portions of the insulation layer 146 are removed to form an encapsulating layer 132 including recesses 132r. The positions of the recesses 132r may be corresponded to the positions of the cutting lines in the subsequent singulation process. In some embodiments, the cutting process (e.g., a cutting process using a laser or a blade) applied in the singulation process may be used to form the recesses 132r. In some embodiments, the recess 132r may be formed between neighboring two electronic units EL. In some embodiments, the level height of the bottom surface BS1 of the recess 132r may be higher than the level height of the top surface 100ts of the electronic element 100 and lower than the level height of the bottom surface 142abs of the conductive wire 142a of the conductive layer 142 that is extended horizontally. Under such configurations, there are sufficient spaces for filling underfills (e.g., the underfills UF1 shown in FIG. 10), and therefore the adhesion to a printed circuit board (e.g., the printed circuit board PCB shown in FIG. 10) can be increased. In some embodiments, the depth of the recess 132r may be about 10 μm to about 25 μm respective to the top surface of the encapsulating layer 132.

Next, conductive layers 150 are formed on the exposed surfaces of the conductive layer 144s to form a circuit structure CS. The conductive layers 150 may each include a first portion 150a formed on the top surface of the conductive layer 144 and a second portion 150b formed on the side surface of the conductive layer 144 exposed by the space above the recess 132r (e.g., the space formed by removing the portion of the insulation layer 146). The conductive layer 150 may each include any suitable conductive material, for example, copper (Cu), aluminum (Al), nickel (Ni), molybdenum (Mo), titanium (Ti), gold (Au), tin (Sn), gallium (Ga), ruthenium (Ru), tantalum (Ta), alloys or combinations of the above materials, or other suitable materials, but is not limited thereto. In some embodiments, the conductive layers 150 may be, for example, electroless nickel immersion gold (ENIG), but are not limited thereto.

Then, referring to FIG. 1C and FIG. 1D, the structure formed as shown in FIG. 1C is flipped over and placed on another carrier substrate Csub2, and may be fixed, in this embodiment, through a bonding layer TBL2 formed on the carrier substrate Csub2. Subsequently, the bonding layer TBL1 may lose its adhesiveness through, for example, heating or light exposure, so as to remove the bonding layer TBL1 and the carrier substrate Csub1. The material of the carrier substrate Csub2 may include quartz, glass, stainless steel, sapphire, other suitable materials or combinations of the above, but is not limited thereto. In some embodiments, the bonding layer TBL2 may be a temporary bonding layer, which may include a thermal-type or an optical-type release material having adhesiveness, so that working units, elements or film layers subsequently formed thereon can be temporarily adhered to to the bonding layer TBL2. For example, the bonding layer TBL2 may be a thermal release tape (HRT) or a light-to-heat-conversion (LTHC) release coating. In the case where the optical-type release material is used to form the bonding layer TBL2, the optical-type release material loses its adhesiveness when exposed to radiation such as an ultra-violet light (UV light), so that the elements or the film layers formed thereon may be peeled off from the bonding layer TBL2. For example, the bonding layer TBL2 may be a UV paste.

Subsequently, an adhesive layer 160 is provided on the encapsulating layer 132. As shown in FIG. 1D, the adhesive layer 160 may be provided on a side (e.g., a back side) of the electronic element 100 opposite to the side (e.g., the front side) where the conductive pad 102 is located. The adhesive layer 160 may be any suitable adhesive. For example, according to some embodiments, the adhesive layer 160 may include an epoxy resin, a die attach film (DAF), a thermal interface material (TIM), other suitable adhesive materials or combinations of the above, but is not limited thereto. According to some embodiments, the adhesive layer 160 may contact a surface of the electronic element 100, and the adhesive layer 160 may include materials with heat dissipation function, such as a silicone adhesive sheet, but is not limited thereto. The adhesive layer 160 may include adhesive materials with heat dissipation particles, such as an epoxy resin including graphite particles or an epoxy resin including ceramic heat dissipation particles, but is not limited thereto.

Then, a conductor layer 170 is provided on the adhesive layer 160, where the circuit structure CS and the conductor layer 170 are corresponded to opposite sides of the encapsulating layer 132, (e.g., the upper side and lower side of the encapsulating layer 132). In other words, the connection elements 120 may be provided between the circuit structure CS and the conductor layer 170. In some embodiments, the conductor layer 170 may serve as a heat sink, such as a heat dissipation sheet, so that the heat generated by the electronic element 100 during the operation can be dissipated from the conductor layer 170. In some embodiments, the thermal conductivity of the connection element 120 may be the same as or different from the thermal conductivity of the conductor layer 170. For example, the ratio of the thermal conductivity of the connection element 120 to the thermal conductivity of the conductor layer 170 may be between 0.5 and 1.2 to improve heat transfer from inner to outer (e.g., a heat dissipation path HDP shown in FIG. 2A), but not limited to. In the case where the conductor layer 170 is used as a heat sink, the conductor layer 170 may be made of, for example, any suitable heat conductive material, but is not limited thereto. In other embodiments, in the case where the electronic device includes a back-side wiring formed on the back side of the electronic elements 100, the conductor layer 170 may also serve as a conductive layer for the back-side wiring. In this case, the conductor layer 170 may be made of, for example, any suitable conductive material, but is not limited thereto. In some embodiments, the thermal conductivity of the adhesive layer 160 is smaller than the thermal conductivity of the conductor layer 170, and the thermal conductivity of the adhesive layer 160 is smaller than the thermal conductivity of the conductor layer 120. In some embodiments, a thermal diffusivity of the adhesive layer 160 is greater than a thermal diffusivity of the conductor layer 170, and a thermal diffusivity of the adhesive layer 160 is greater than a thermal diffusivity of the conductor layer 120, so as to say that the adhesive layer 160 is used to transfer heat from inner to outer along X-Y direction.

After that, referring to FIG. 1D and FIG. 1E, a singulation process is performed to form the electronic device 10. In this embodiment, the singulation process is performed by performing another cutting process (e.g., using a laser cutting process or a blade cutting process) again at the positions of the recesses 132r to form the electronic device 10. After forming the electronic device 10, a process such as heating or light exposure may be applied to the bonding layer TBL2, so as to lose its adhesiveness, and thereby removing the bonding layer TBL2 and the carrier substrate Csub2. In some embodiments, a sidewall of the encapsulating layer 132 where the recess 132r is formed may include a first surface (e.g., a surface including a sidewall SW1 and/or a bottom surface BS1 of the recess 132r) defining the recess 132r and a second surface (e.g., a surface of the first side S1 or the second side S2) below the recess 132r, and a surface roughness of the first surface may be different from a surface roughness of the second surface.

The electronic device 10 will be described in the following with reference to FIG. 1E. The electronic device 10 shown in FIG. 1E may be formed by the method described above, but is not limited thereto. The electronic device 10 may include at least one electronic unit EL, an encapsulating layer 132, a circuit structure CS, a conductor layer 172, and a connection element 120. The encapsulating layer 132 may surround the electronic unit EL. The circuit structure CS is electrically connected to at least one electronic unit EL. The circuit structure CS and the conductor layer 172 is corresponded to opposite sides (e.g., the upper side and the lower side) of the encapsulating layer 132. The connection element 120 may be disposed between the circuit structure CS and the conductor layer 172, wherein the encapsulating layer 132 surrounds the connection element 120 and includes a recess 132r. In some embodiments, the electronic device 10 may further include an adhesive layer 162 disposed between the encapsulating layer 132 and the conductor layer 172.

In some embodiments, as shown in FIG. 1F, the conductive layer 144 in the circuit structure CS may extend at least partially into the recess 132r. In some embodiments, the portion of the conductive layer 144 extending into the recess 132r may have a length less than or equal to half of the thickness of the insulation layer 146. In other embodiments, the length of the conductive layer 144 extending into the recess 132r may be less than or equal to half of the entire thickness of the encapsulating layer 132. In some alternative embodiments, the length of the conductive layer 144 extending into the recess 132r may be less than or equal to half of the maximum depth of the recess 132r. In some embodiments, the second portion 150b of the conductive layer 150 may extend at least partially into the recess 132r. A part of the second portion 150b of the conductive layer 150 extending into the recess 132r may have a length less than or equal to half of the thickness of the insulation layer 146. In some embodiments, the conductive layer 144 may have a protrusion at the corner connecting its top surface and side surface, wherein the conductive layer 150 covers the protrusion.

In some embodiments, as shown in FIG. 1E, the recess 132r of the encapsulating layer 132 may include a curved surface. In the horizontal direction (e.g., direction X), the width of the portion of the encapsulating layer 132 where the recess 132r is formed may be smaller than the maximum width of the encapsulating layer 132. In this disclosure, the aforementioned “width” may be, for example, a dimension measured along a direction perpendicular to direction Z. In some embodiments, since the recess 132r is formed by the cutting process different from the cutting process used in the above singulation process (e.g., the recess 132r is formed by a first cutting process, and the cutting process in the singulation process is a second cutting process different from the first cutting process), the surface roughness of the encapsulating layer 132 where the recess 132r is formed (e.g., the surface roughness of the aforementioned curved surface) may be different from the surface roughness of the side surface of the encapsulating layer 132 below the recess 132r.

In some embodiments, as shown in FIG. 1G, the encapsulating layer 132 may include a first side S1 and a second side S2 opposite to each other in the horizontal direction (e.g., direction X or direction Y), wherein recesses 132r are formed in the first side S1 and the second side S2, respectively. One of the first side S1 and the second side S2 may be at an angle (01 or 02) of less than 45 degrees to the sidewall of the electronic element 100 of the electronic unit EL facing the one of the first side S1 and the second side S2. Accordingly, the influence on the electrical connection between the electronic elements 100 caused by the excessive offset can be reduced.

In some embodiments, as shown in FIG. 2A, the surface of the encapsulating layer 132 of the electronic device 12 facing the conductor layer 172 and the surface of the electronic unit EL facing the conductor layer 172 may have a gap of 1 μm to 10 μm (e.g., the height h1 illustrated in FIG. 2A), so that the materials are bonded firmly with each other, and thus the reliability or the quality of the electronic device 12 can be enhanced.

In some embodiments, as shown in FIG. 2B, the electronic unit EL of the electronic device 14 may include an insulation layer 104 formed on the electronic element 100, wherein the insulation layer 104 may be formed on a side (e.g., a front side) of the electronic element 100 where the conductive pads 102 are formed. The conductive vias 142b may penetrate through the insulation layer 104 to electrically connect with the conductive pads 102. The insulation layer 104 may include any suitable insulation material, for example, silicon oxide, silicon nitride, or a combination thereof, but is not limited thereto.

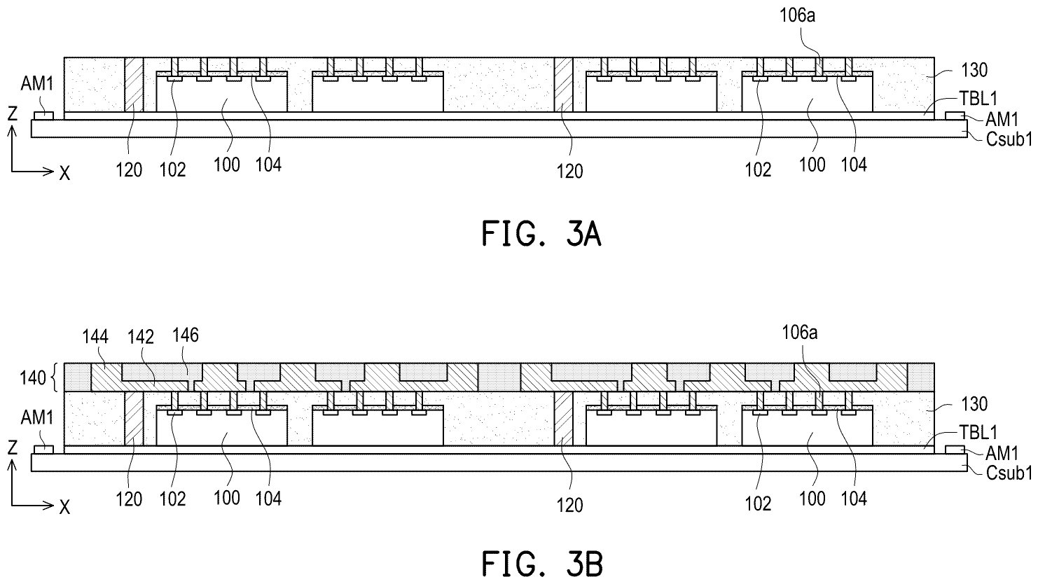

FIG. 3A and FIG. 3B are cross-sectional schematic views of a manufacturing method of an electronic device according to the second embodiment of the present disclosure. The manufacturing method illustrated in FIG. 3A and FIG. 3B is similar to the manufacturing method illustrated in FIG. 1A and FIG. 1B. The main difference therebetween are as follows: the insulation layer 110 on the electronic element 100 (as shown in FIG. 1A) is replaced with the insulation layer 104 (as shown in FIG. 3A); and as shown in FIG. 3A, in the process before the circuit structure 140 is provided and after the encapsulating layer 130 is ground to expose the top surface of the connection element 120, pillar holes corresponding to the conductive pads 102 are formed in the encapsulating layer 130 through a patterning process including a drilling process (e.g., a laser drilling process). The holes penetrate through the encapsulating layer 130 and the insulation layer 104 and expose the conductive pads 102. Then, conductive materials are filled into the holes to form conductive pillars 106a electrically connected to the conductive pads 102. In this embodiment, the amount of the conductive pillars 106a may correspond to the amount of the conductive pads 102. The conductive pillars 106a may include any suitable conductive material, for example, copper (Cu), aluminum (Al), nickel (Ni), molybdenum (Mo), titanium (Ti), alloys or combinations of the above materials, or other suitable materials, but are not limited thereto. Then, as shown in FIG. 3B, the circuit structure 140 is provided on the encapsulating layer 130. In detail, the circuit structure 140 is provided according to an offset result including a displacement data of at least one electronic element 100 surrounded by the encapsulating layer 130 to reduce electrical issue of the electronic unit EL. After a real position of the circuit structure 140 is defined, the circuit structure 140 is provided on the encapsulating layer 130. In this embodiment, the circuit structure 140 may include a conductive layer 142 electrically connected to the conductive pillars 106a, a conductive layer 144 disposed on the conductive layer 142, and an insulation layer 146 covering the conductive layer 142 and surrounding the conductive layer 144.

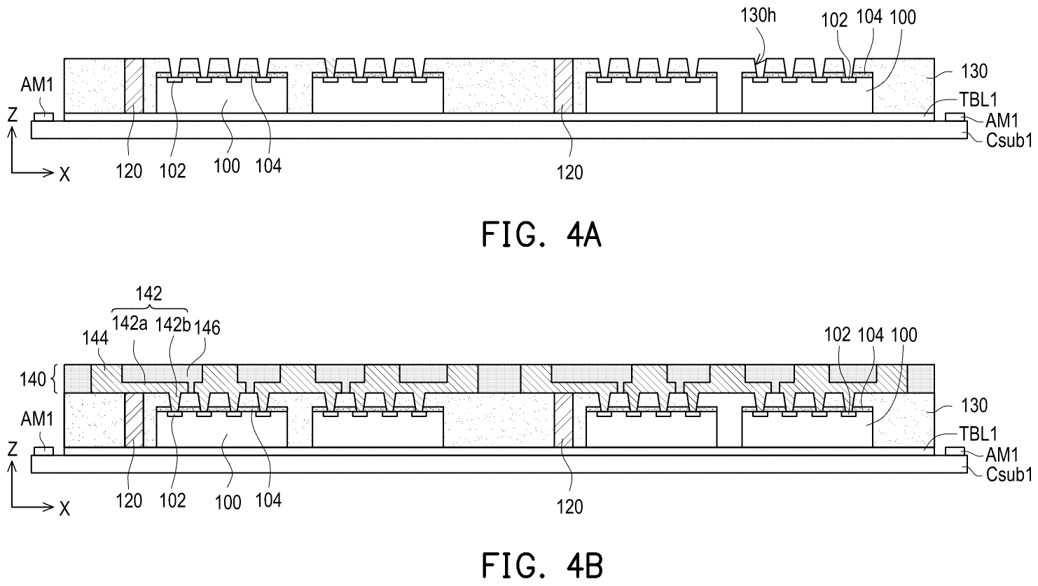

FIG. 4A and FIG. 4B are cross-sectional schematic views of a manufacturing method of an electronic device according to the third embodiment of the present disclosure. The manufacturing method illustrated in FIG. 4A and FIG. 4B is similar to the manufacturing method illustrated in FIG. 3A and FIG. 3B. The main differences therebetween are that in the process before the circuit structure 140 is provided and after the encapsulating layer 130 is ground to expose the top surface of the connection element 120, inverted trapezoidal holes 130h corresponding to the conductive pads 102 are formed in the encapsulating layer 130 through a patterning process including an etching process (as shown in FIG. 4A). The holes 130h penetrate through the encapsulating layer 130 and the insulation layer 104 and expose the conductive pads 102. Then, as shown in FIG. 4B, the circuit structure 140 is provided on the encapsulating layer 130. In this embodiment, the circuit structure 140 may include a conductive layer 142, a conductive layer 144 disposed on the conductive layer 142, and an insulation layer 146 covering the conductive layer 142 and surrounding the conductive layer 144. In this embodiment, the conductive layer 142 may include conductive wires 142a extending horizontally and conductive vias 142b filled into the inverted trapezoidal holes 130h to electrically connect with the conductive pads 102.

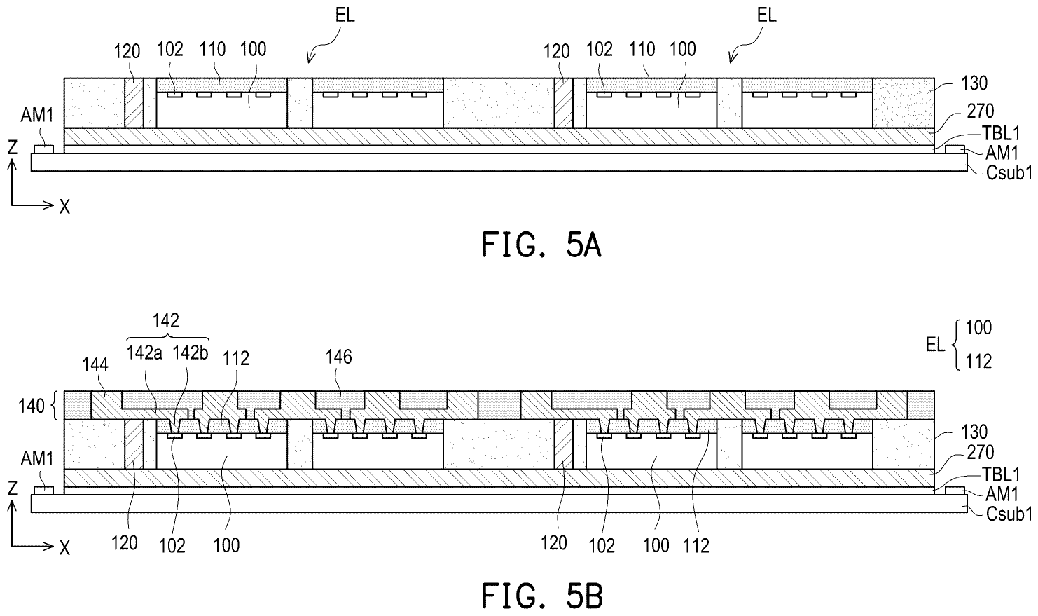

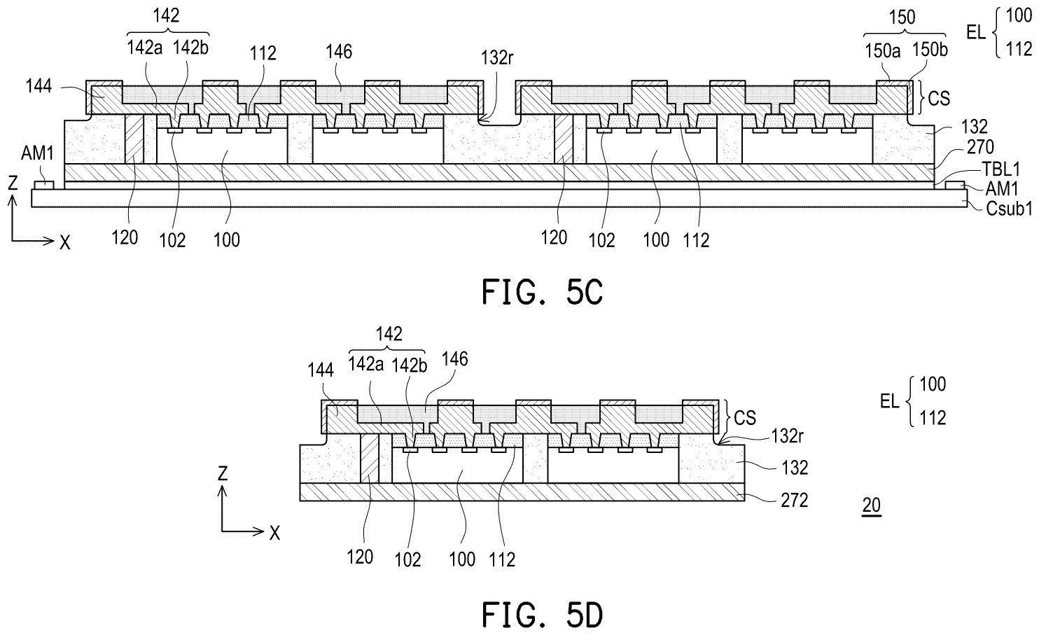

FIG. 5A to FIG. 5D are cross-sectional schematic views of a manufacturing method of an electronic device according to the fourth embodiment of the present disclosure. The manufacturing method illustrated in FIG. 5A to FIG. 5D is similar to the manufacturing method illustrated in FIG. 1A to FIG. 1E. The main differences therebetween are that the conductor layer 270 is firstly provided on the carrier substrate Csub1, and then the electronic unit EL is provided on the conductor layer 270 (as shown in FIG. 5A). In other words, the manufacturing method illustrated in FIG. 5A to FIG. 5D may omit the flipping step shown in FIG. 1C to FIG. 1D. As a result, the degradation of the encapsulating layer can be avoided by reducing the number of flipping operations, thereby enhancing the reliability or the quality of the electronic device.

In some embodiments, the manufacturing method of the electronic device (such as the electronic device 20 shown in FIG. 5D) may include the following steps.

First, as shown in FIG. 5A, the conductor layer 270 is provided on the carrier substrate Csub1 which a bonding layer TBL1 and alignment marks AM1 are formed thereon and the conductor layer 270 is bonded to the carrier substrate Csub1 through the bonding layer TBL1. Then, the electronic units EL and the connection elements 120 are provided on the conductor layer 270. Specifically, the method of providing the connection elements 120 includes a process of electroplating or electroless plating conductive elements on the conductor layer 270, but is not limited thereto. Next, an encapsulating layer 130 surrounding the plurality of electronic units EL and connection elements 120 is provided. In some embodiments, the conductor layer 270 may serve as a conductive layer for the backside wirings formed on the back surface of the electronic element. In this case, the conductor layer 270 may be made of, for example, any suitable conductive material, but is not limited thereto. In other embodiments, the conductor layer 270 may also serve as a heat sink, such as a heat dissipation sheet, so that the heat generated by the electronic elements 100 during the operation can be dissipated from the conductor layer 270. In this case, the conductor layer 270 may be made of, for example, any suitable thermally conductive material, but is not limited thereto.

Next, referring to FIG. 5A and FIG. 5B, a circuit structure 140 electrically connected to the electronic units EL is provided. In this embodiment, the circuit structure 140 may include a conductive layer 142, a conductive layer 144 disposed on the conductive layer 142, and an insulation layer 146 covering the conductive layer 142 and surrounding the conductive layer 144. In some embodiments, the conductive layer 142 may include conductive wires 142a extending horizontally and conductive vias 142b extending vertically and passing through the insulation layers 112 and electrically connect to the conductive pads 102.

Then, referring to FIG. 5B and FIG. 5C, portions of the insulation layer 146 and portions of the encapsulating layer 130 under the portions of the insulation layer 146 are removed to form an encapsulating layer 132 including recesses 132r. The positions of the recesses 132r may be corresponded to the positions of the cutting lines in the subsequent singulation process. In some embodiments, the cutting process used in the singulation process (e.g., a cutting process using a laser or a blade) may be used to form the recesses 132r. In some embodiments, the recess 132r may be formed between the neighboring two electronic units EL.

Then, conductive layers 150 are formed on the exposed surfaces of the conductive layer 144 to form the circuit structure CS. The conductive layers 150 may each include a first portion 150a formed on the top surface of the conductive layer 144 and a second portion 150b formed on the side surface of the conductive layer 144 exposed by the space above the recess 132r (e.g., the space formed by removing the portion of the insulation layer 146).

Subsequently, referring to FIG. 5C and FIG. 5D, a singulation process is performed to form the electronic device 20. In this embodiment, the singulation process is performed by performing another cutting process (e.g., a cutting process using the laser or the blade) again at the positions of the recesses 132r to form the electronic device 20. After forming the electronic device 20, a process such as heating or light exposure may be applied to the bonding layer TBL1, so as to lose its adhesiveness, and thereby removing the bonding layer TBL1 and the carrier substrate Csub1.

The electronic device 20 will be described in the following with reference to FIG. 5D. The electronic device 20 shown in FIG. 5D may be formed by the method described above, but is not limited thereto. The electronic device 20 may include at least one electronic unit EL, an encapsulating layer 132, a circuit structure CS, a conductor layer 272, and a connection element 120. The encapsulating layer 132 may surround the electronic unit EL. The circuit structure CS is electrically connected to at least one electronic unit EL. The circuit structure CS and the conductor layer 272 are corresponded to opposite sides (e.g., the upper side and the lower side) of the encapsulating layer 132. The connection element 120 may be disposed between the circuit structure CS and the conductor layer 272, wherein the encapsulating layer 132 surrounds the connection element 120 and includes a recess 132r. In some embodiments, the circuit structure CS may be electrically connected to the conductor layer 272 through the connection element 120. In some embodiments, the connection element 120 and the conductor layer 272 may be a structure formed integrally (e.g., a frame).

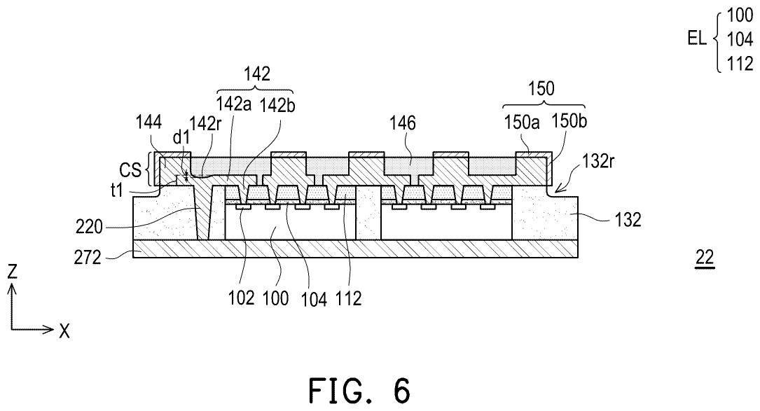

FIG. 6 is a cross-sectional schematic view of an electronic device according to yet another embodiment of the present disclosure. The electronic device 22 shown in FIG. 6 is similar to the electronic device 20 shown in FIG. 5D. The main difference therebetween is that the connection element 220 of the electronic device 22 may be a through mold via (TMV) formed in the encapsulating layer 130. In this embodiment, the connection element 220 may be formed, for example, by the following steps. First, a via hole is formed in the encapsulating layer 130. Then, a seed layer (not shown) is formed on the surface of the via hole. Subsequently, the seed layer is grown through an electroplating process to form the connection element 220. In this embodiment, the conductive layer 142 may include another recess 142r overlapping with the connection element 220. In other words, the circuit structure CS of the electronic device 22 shown in FIG. 6 may include at least one conductor structure (e.g., a conductor structure including the conductive layer 142 and the conductive layer 144), and the conductor structure includes another recess 142r overlapping with the connection element 220. In some embodiments, a ratio of a depth d1 of the recess 142r to a thickness t1 of the conductive wire 142a (i.e., d1/t1) may range from 0.01 to 0.3, or may range from 0.05 to 0.2, so as to increase the contact area between the conductive layer 142 and the insulation layer 146, or to prevent the insulation layer 146 from being delaminated from the conductive layer 142, but is not limited thereto.

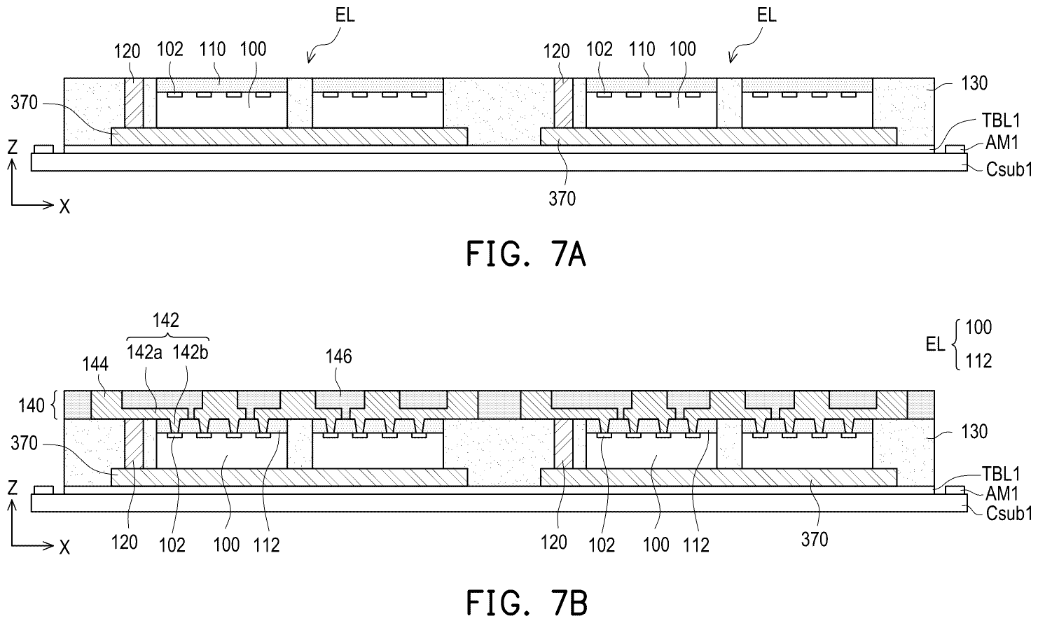

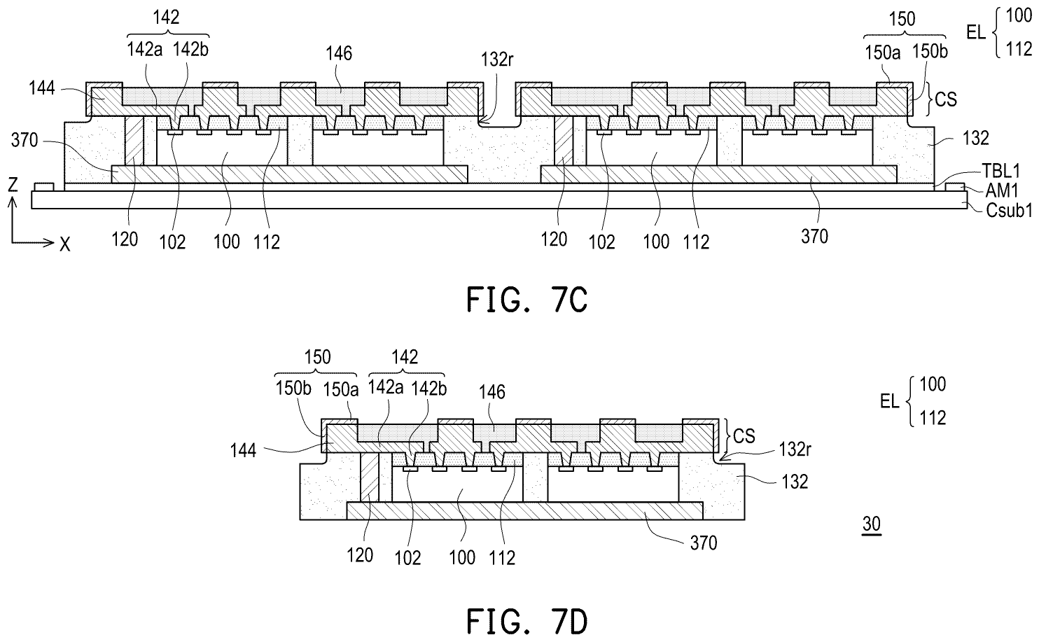

FIG. 7A to FIG. 7D are cross-sectional schematic views of a manufacturing method of an electronic device according to the fifth embodiment of the present disclosure. The manufacturing method shown in FIG. 7A to FIG. 7D is similar to the manufacturing method shown in FIG. 5A to FIG. 5D. The main difference therebetween is that the conductor layer 370 shown in FIG. 7A is formed to be plural and provided on the carrier substrate Csub1, respectively.

In some embodiments, the manufacturing method of the electronic device (such as the electronic device 30 shown in FIG. 7D) may include the following steps.

First, as shown in FIG. 7A, a plurality of conductor layers 370 are provided respectively on a carrier substrate Csub1 which a bonding layer TBL1 and alignment marks AM1 are formed thereon, and the conductor layers 370 are bonded to the carrier substrate Csub1 through the bonding layer TBL1. Next, electronic units EL and connection elements 120 are provided on the conductor layers 370. Then, an encapsulating layer 130 surrounding the electronic units EL, connection elements 120, and conductor layers 370 is provided. In some embodiments, the conductor layers 370 may serve as conductive layers for the backside wirings formed on the back sides of the electronic elements 100. In this case, the conductor layers 370 may be made of, for example, any suitable conductive materials, but are not limited thereto. In other embodiments, the conductor layers 370 may also serve as heat sinks, such as heat dissipation sheets, so that the heat generated by the electronic elements 100 during the operation can be dissipated from the conductor layers 370. In this case, the conductor layers 370 may be made of, for example, any suitable heat-conductive materials, but are not limited thereto. In this embodiment, the amount of the conductor layers 370 may be corresponded to the amount of the electronic units EL.

Next, referring to FIG. 7A and FIG. 7B, a circuit structure 140 electrically connected to the electronic units EL is provided. In this embodiment, the circuit structure 140 may include a conductive layer 142, a conductive layer 144 disposed on the conductive layer 142, and an insulation layer 146 covering the conductive layer 142 and surrounding the conductive layer 144. In some embodiments, the conductive layer 142 may include conductive wires 142a extending horizontally and conductive vias 142b extending vertically through the insulation layers 112 and electrically connected to the conductive pads 102.

Subsequently, referring to FIG. 7B and FIG. 7C, portions of the insulation layer 146 and portions of the encapsulating layer 130 under the portions of the insulation layer 146 are removed to form an encapsulating layer 132 including recesses 132r. The positions of the recesses 132r may be corresponded to the positions of the cutting lines in the subsequent singulation process. In some embodiments, the cutting process used in the singulation process (e.g., a cutting process using a laser or a blade) may be used to form the recesses 132r. In some embodiments, the recesses 132r may be formed between the neighboring two electronic units EL.

Then, conductive layers 150 are formed on the exposed surfaces of the conductive layer 144 to form a circuit structure CS. The conductive layers 150 may each include a first portion 150a formed on the top surface of the conductive layer 144 and a second portion 150b formed on the side surface of the conductive layer 144 exposed by the space above the recess 132r (e.g., the space formed by removing the portion of the insulation layer 146).

Subsequently, referring to FIG. 7C and FIG. 7D, a singulation process is performed to form the electronic device 30. In this embodiment, the singulation process is performed by performing another cutting process (e.g., a cutting process using the laser or the blade) again at the positions of the recesses 132r to form the electronic device 30. After forming the electronic device 30, a process such as heating or light exposure may be applied to the bonding layer TBL1 so as to lose its adhesiveness, and thereby removing the bonding layer TBL1 and the carrier substrate Csub1. In this embodiment, the conductor layers 370 are not formed below the recesses 132r, so that the cutting process used in the above singulation process does not cut the conductor layers 370. In some embodiments, the circuit structure CS may be electrically connected to the conductor layers 370 through the connection elements 120. In some embodiments, the connection elements 120 and the conductor layers 370 may be a structure formed integrally (e.g., a frame).

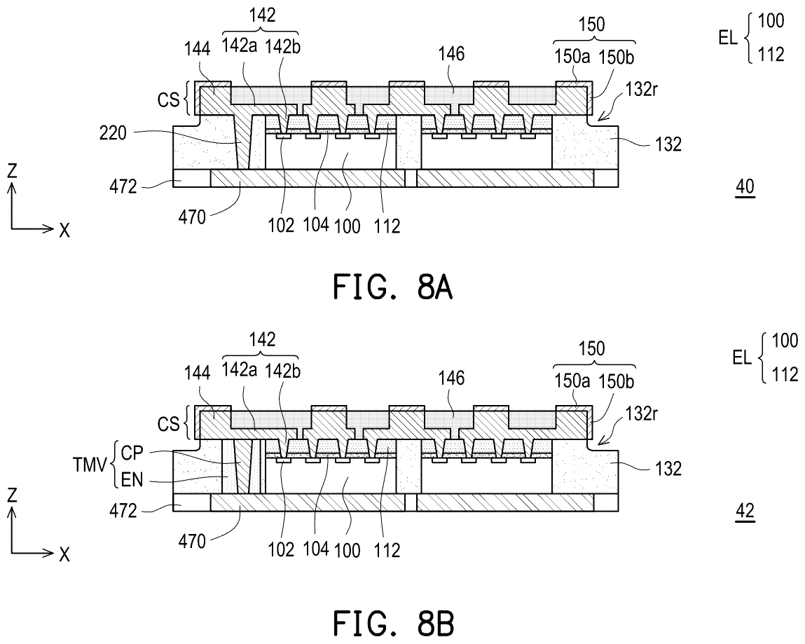

FIG. 8A is a cross-sectional schematic view of an electronic device according to still another embodiment of the present disclosure. The electronic device 40 shown in FIG. 8A is similar to the electronic device 30 shown in FIG. 7D. The main differences therebetween are that: the conductor layers 470 of the electronic device 40 are formed to be plural and are spaced apart from each other by an insulation layer 472 formed between the conductor layers 470; and the method of forming the connection element 220 is different from that of the connection element 120 shown in FIG. 7D. The connection element 220 shown in FIG. 8A is formed by using the same method as the connection element 220 shown in FIG. 6, for example. In this embodiment, the electronic elements 100 may be provided on the conductor layers 470, respectively. In other words, the amount of the conductor layers 470 shown in FIG. 8A may be corresponded to the amount of the electronic elements 100.

FIG. 8B is a cross-sectional schematic view of an electronic device according to still yet another embodiment of the present disclosure. The electronic device 42 shown in FIG. 8B is similar to the electronic device 40 shown in FIG. 8A. The main difference therebetween is that the connection element TMV of the electronic device 42 is formed in other production lines, and then the finished connection element TMV is provided on the conductor layer 470. In other words, the connection element TMV may include a conductive via (e.g., conductive pillar) CP and an insulation layer EN surrounding the conductive via CP. The insulation layer EN may be made of, for example, any suitable insulation material. In some embodiments, the insulation layer EN may be made of a material similar to the encapsulating layer 132. The connection element TMV may be formed, for example, by the following steps. First, a plurality of through mold vias (TMV) are formed in an encapsulating layer (e.g., an encapsulating layer in the other production lines different from the encapsulating layer 130). Then, a singulation process is performed on the plurality of through mold vias formed in the encapsulating layer to form the connection elements TMV.

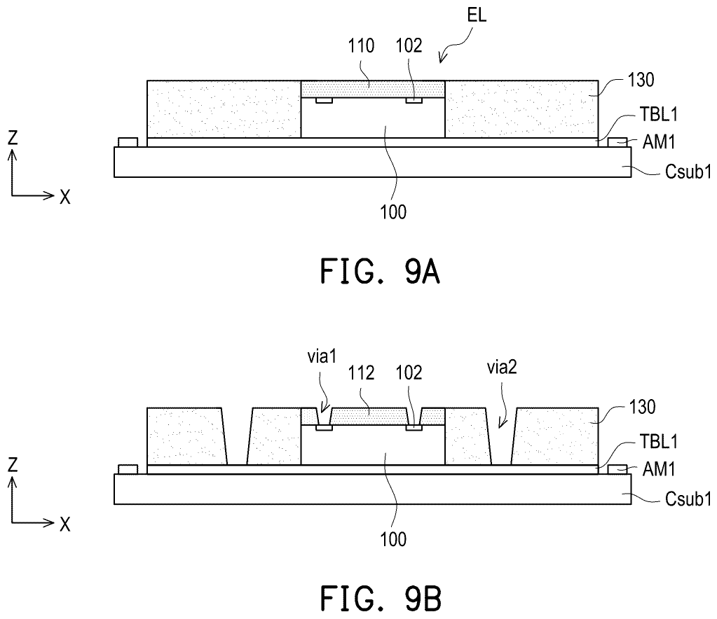

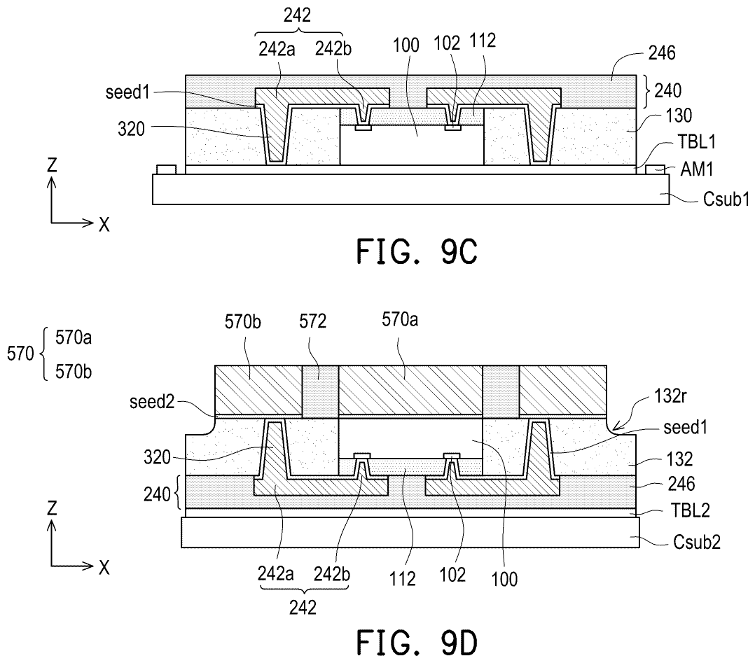

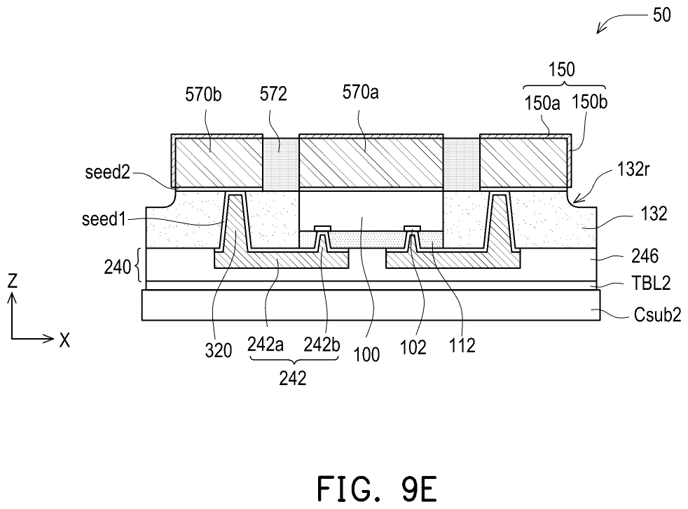

FIG. 9A to FIG. 9E are cross-sectional schematic views of a manufacturing method of an electronic device according to the sixth embodiment of the present disclosure. The manufacturing method shown in FIG. 9A to FIG. 5E is similar to the manufacturing method shown in FIG. 1A to FIG. 1E. The main differences therebetween are that: the method of forming the connection elements 320 of the electronic device 50 is different from that of the connection element 120 of the electronic device 10; and the manufacturing method and structure of the conductor layers 570 are different from the conductor layers 170 of the first embodiment.

First, referring to FIG. 9A, an electronic unit EL is provided on a carrier substrate Csub1 which alignment marks AM1 and a bonding layer TBL1 are provided thereon. The electronic unit EL may be fixed on the carrier substrate Csub1 through the bonding layer TBL1. The electronic unit EL may include an electronic element 100 and an insulation layer 110 disposed on the electronic element 100. The electronic element 100 may include conductive pads 102, and the conductive pads 102 may be located on a side (e.g., a front side) of the electronic element 100. FIG. 9A illustrates, as an exemplary embodiment, that the amount of the electronic element 100 included in each electronic unit EL is 1, but the amount of the electronic element 100 is not limited to the amount of the electronic element 100 shown in FIG. 9A.

Then, an encapsulating layer 130 surrounding the electronic unit EL is provided on the bonding layer TBL1. The encapsulating layer 130 may be formed, for example, by the following steps. First, an encapsulating material layer covering the electronic unit EL is formed on the bonding layer TBL1. Next, a portion of the encapsulating material layer located above the top surface of the electronic unit EL is removed, for example, by grinding, to form the encapsulating layer 130. In this embodiment, the top surface of the encapsulating layer 130 may be formed to be coplanar with the top surface of the electronic unit EL (e.g., the top surface of the insulation layer 110).

Subsequently, referring to FIG. 9A and FIG. 9B, a patterning process is performed on the insulation layer 110 and the encapsulating layer 130 to form an insulation layer 112 including via holes via1 and an encapsulating layer 130 including via holes via2. The patterning process may include a drilling process or an etching process. The via holes via1 may expose portions of the conductive pads 102 of the electronic element 100, and the via holes via2 may expose portions of the bonding layer TBL1.

Then, referring to FIG. 9B and FIG. 9C, a seed layer seed1 is formed on the surfaces of the via holes via1 and the via holes via2. In this embodiment, the seed layer seed1 is formed on the top surfaces of the encapsulating layer 130 and the insulation layer 112 between the via holes via1 and the via holes via2. In some embodiments, the seed layer seed1 is also formed on the top surface of the insulation layer 112 around the via holes via1 and on the top surface of the encapsulating layer 130 around the via holes via2. The seed layer seed1 may include any suitable conductive material, for example, titanium, copper, aluminum, nickel, or combinations thereof, but is not limited thereto. Next, the seed layer seed1 is grown through an electroplating process, so that connection elements 320 are formed in the via holes via2, and a conductive layer 242 of the circuit structure 240 is formed on the encapsulating layer 130 in which the conductive layer 242 includes conductive wires 242a extending horizontally and conductive vias 242b filled into the via holes via1 and electrically connected to the conductive pads 102. Subsequently, an insulation layer 246 covering the conductive layer 242 is formed on the encapsulating layer 130 and the insulation layer 112 to form the circuit structure 240. The conductive layer 242 may include any suitable conductive material, for example, copper, titanium, nickel, combinations or alloys of the above materials, but is not limited thereto. The insulation layer 246 may include any suitable insulation material, for example, build-up layer, polyimide, resin (such as epoxy resin), silicon oxide, silicon nitride, solder resist, or combinations thereof, but is not limited thereto.

Subsequently, referring to FIG. 9C and FIG. 9D, the structure formed as shown in FIG. 9C is flipped over and placed on another carrier substrate Csub2, and may be fixed, in this embodiment, through a bonding layer TBL2 formed on the carrier substrate Csub2. Then, the bonding layer TBL1 may lose its adhesiveness through, for example, heating or light exposure, so as to remove the bonding layer TBL1 and the carrier substrate Csub1. Next, a seed layer seed2 may be formed on the encapsulating layer 130. The seed layer seed2 may include any suitable conductive material, for example, titanium, copper, aluminum, nickel, or combinations thereof, but is not limited thereto. Afterwards, a conductor layer of the circuit structure is formed on the seed layer seed2 through an electroplating process, and then a conductive layer 570 and an encapsulating layer 132 including recesses 132r are formed by removing portions of the conductor layer of the circuit structure and portions of the seed layer seed2 and the encapsulating layer 130 below the portions of the conductor layer. The positions of the recesses 132r may be corresponded to the positions of the cutting lines in the subsequent singulation process. In some embodiments, the cutting process used in the singulation process (e.g., a cutting process using a laser or a blade) may be used to form the recesses 132r. The conductor layer 570 may include a first portion 570a overlapping with the electronic elements 100 and a second portion 570b connected to the connection elements 320. The circuit structure may include an insulation layer 572 that separates the first portion 570a and the second portion 570b of the conductor layer 570. The insulation layer 572 may include any suitable insulation material. In some embodiments, the surface of the electronic element 100 facing the seed layer seed2 may be higher than the surface of the encapsulating layer 132 facing the insulation layer 572 and around the surface of the electronic element 100 facing the seed layer seed2, such that the thickness of the seed layer seed2 below the first portion 570a may be smaller than the thickness of the seed layer seed2 below the second portion 570b.

Then, referring to FIG. 9D and FIG. 9E, conductive layers 150 are formed on the exposed surfaces of the conductor layer 570. The conductive layers 150 may include first portions 150a formed on the top surface of the first portion 570a and top surfaces of the second portions 570b of the conductor layer 570, and second portions 150b formed on the sidewalls of the second portions 570b of the conductor layer 570 exposed by the spaces above the recesses 132r.

FIG. 10 is a cross-sectional schematic view of an electronic device according to an embodiment of the present disclosure. The electronic device 60 shown in FIG. 10 is similar o the electronic device 14 shown in FIG. 2B. The main difference therebetween is that the electronic device 60 further includes a printed circuit board PCB, a plurality of contact elements CE1 and CE2, underfills UF1 and UF2, and an electronic element 200.

In this embodiment, as shown in FIG. 10, the package structure including the electronic units EL and the encapsulating layer 132 may be electrically connected to the printed circuit board PCB through the plurality of contact elements CE1. In this embodiment, the contact elements CE1 may include solder balls. The material of the contact elements CE1 may include tin-silver (SnAg), tin, silver, nickel, gold, copper, conductive adhesive, or other suitable conductive materials, but is not limited thereto.

In this embodiment, as shown in FIG. 10, portions of the underfill UF1 are in contact with portions of the encapsulating layer 132 where the recesses 132r are formed, that is, the underfill UF1 fills into the recesses 132r or is in contact with at least portions of the first and second sides S1 and S2 of the encapsulating layer 132, and thereby enhancing the contact area between the underfill UF1 and the encapsulating layer 132, thereby improving the reliability or the quality of the electronic device 60.

In this embodiment, as shown in FIG. 10, the electronic element 200 may be disposed on the printed circuit board PCB and may be electrically connected to the package structure through the printed circuit board PCB. The electronic element 200 may include other electronic elements such as capacitors, but is not limited thereto. In this embodiment, the electronic element 200 may be electrically connected to the printed circuit board PCB through the contact elements CE2. In this embodiment, the contact elements CE2 may include solder balls. The material of the contact elements CE2 may include tin-silver (SnAg), tin, silver, nickel, gold, copper, conductive adhesive, or other suitable conductive materials, but is not limited thereto. In this embodiment, as shown in FIG. 10, the underfill UF2 surrounding the contact elements CE2 may be filled in the space between the electronic element 200 and the printed circuit board PCB to enhance the reliability or the quality of the electronic device 60.

In some embodiments, the electronic device 60 may further includes electronic elements 1000, 2000 and 3000 disposed on a side of the printed circuit board PCB opposite to a side of the printed circuit board PCB where the electronic element 200 is disposed thereon, and an underfill UF3 covering the electronic elements 1000, 2000 and 3000. The underfill UF3 may serve as a protective layer for waterproofing, impact protection, or other suitable functions. In some embodiment, the electronic elements 1000, 2000 and 3000 may be electrically connected to the printed circuit board PCB. In some embodiment, the electronic elements 1000, 2000 and 3000 may each include elements similar to the electronic element 200, but are not limited thereto. The underfill UF3 may be made of materials similar to the underfill UF1 or the underfill UF2, but is not limited thereto.

In some embodiments, the encapsulating layer 132 includes a first side and a second side opposite to each other in the horizontal direction (e.g., direction X), where the recesses 132r are formed respectively (e.g., the first side S1 and the second side S2 shown in FIG. 1E). The first side and the second side are spaced apart by a width W1 in the horizontal direction. The maximum width of the recess 132r on the first side in the horizontal direction is W2, and the maximum width of the recess 132r on the second side in the horizontal direction is W3, and (W2+W3)/W1*100%≤25%. Within this range, the underfill UF1 can ensure the electrical connection between the package structure and the printed circuit board PCB, as well as the relative position between the package structure and the printed circuit board PCB, and allow the electronic device 60 to have a sufficient line fan-out area as well. In some embodiments, W2 may be about equal to W3.

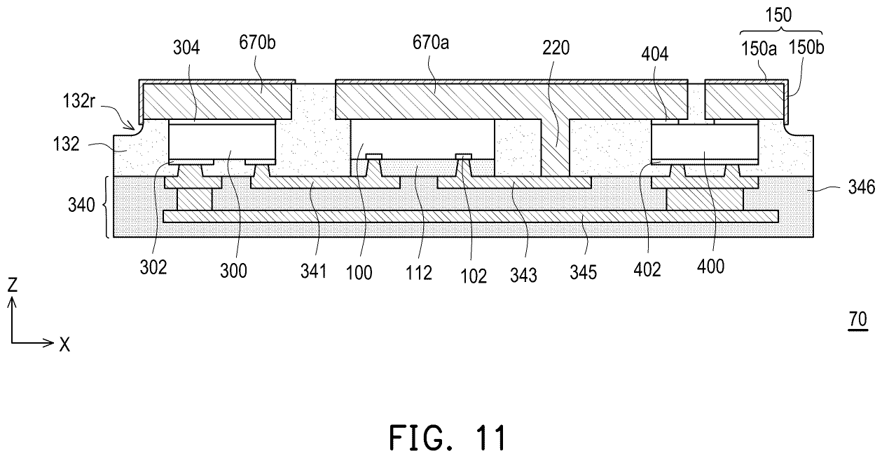

FIG. 11 is a cross-sectional schematic view of an electronic device according to an embodiment of the present disclosure. The electronic device 70 shown in FIG. 11 is similar to the electronic device 50 shown in FIG. 9E. The main differences therebetween are that: the electronic device 70 further includes switch elements 300 and 400 and conductive layers 302, 304, 402 and 404; and the circuit structure 340 is different from the circuit structure 240.

Referring to FIG. 11, in this embodiment, the switch element 300 and the switch element 400 may be disposed in the encapsulating layer 132 and may be located at opposite sides of the electronic element 100 in the horizontal direction (e.g., direction X). In some embodiments, the switch element 300 and the switch element 400 may be switching elements such as transistors. In some embodiments, the switch element 300 and the switch element 400 may be semiconductor elements with different operating voltages. For example, the switch element 300 may be a metal oxide semiconductor field effect transistor (MOSFET) with a high operating voltage, while the switch element 400 may be a MOSFET with a low operating voltage, but the present disclosure is not limited thereto. In this embodiment, the switch element 300 and the switch element 400 may include any suitable semiconductor material.

The circuit structure 340 may include wiring layers 341, 343 and 345 and an insulation layer 346 in which the wiring layers 341, 343 and 345 are disposed. The wiring layer 341 may electrically connect the electronic element 100 to the switch element 300. The wiring layer 343 may electrically connect the electronic element 100 to the connection element 220. The wiring layer 345 may electrically connect the switch element 300 to the switch element 400. In some embodiments, the wiring layer 345 may be used to conduct an electrical connection between the source/drain (not shown) of the switch element 300 and the switch element 400 to reduce noise during signal transmission. The wiring layers 341, 343 and 345 may include any suitable conductive material, such as copper, titanium, nickel, gallium (Ga), ruthenium (Ru), tantalum (Ta), combinations or alloys of the above materials, but are not limited thereto. The insulation layer 346 may include any suitable insulation material, such as build-up layer, polyimide, resin (e.g., epoxy resin), silicon oxide, silicon nitride, solder resist, or combinations thereof, but is not limited thereto.

The conductive layer 302 and the conductive layer 304 may be disposed at opposite sides of the switch element 300 (e.g., at opposite sides in direction Z) and electrically connected to the wiring layer (e.g., wiring layer 341 and wiring layer 345) of the circuit structure 340 and the second portion 670b of the conductor layer 670, respectively. The conductive layer 302 and the conductive layer 304 may each include any suitable conductive material, such as copper, titanium, nickel, gallium (Ga), ruthenium (Ru), tantalum (Ta), combinations or alloys of the above materials, but are not limited thereto.

The conductive layer 402 and the conductive layer 404 may be disposed at opposite sides of the switch element 400 (e.g., at opposite sides in the direction Z) and electrically connected to the wiring layer (e.g., wiring layer 345) of the circuit structure 340 and the first portion 670a of the conductor layer 670, respectively. The conductive layer 402 and the conductive layer 404 may each include any suitable conductive material, such as copper, titanium, nickel, gallium (Ga), ruthenium (Ru), tantalum (Ta), combinations or alloys of the above materials, but are not limited thereto.

The first portion 670a of the conductor layer 670 may be electrically connected to the electronic element 100 through the connection element 220 and the wiring layer 343. In some embodiments, the connection element 220 and the first portion 670a of the conductor layer 670 may be formed integrally.

In summary, in the embodiments of the present disclosure, the encapsulating layer in the electronic device is designed to include a recess, which may improve the contact area between the underfill and the encapsulating layer, and thus the reliability or the quality of the electronic device can be enhanced.

The above embodiments are used to describe the technical solution of the disclosure and are not a limitation thereof. Although the disclosure has been described in detail with reference to each embodiment above, those having ordinary skill in the art should understand that the technical solution recited in each embodiment above may still be modified, or some or all of the technical features thereof may be equivalently replaced. These modifications or replacements do not make the essence of the corresponding technical solutions depart from the scope of the technical solution of each embodiment of the disclosure.

Although the embodiments of the disclosure and their advantages are disclosed as above, it should be understood that any person with ordinary skill in the art, without departing from the spirit and scope of the disclosure, may make changes, substitutions, and modifications, and features between the embodiments may be mixed and replaced at will to form other new embodiments. In addition, the scope of the disclosure is not limited to the manufacturing processes, machines, manufactures, material compositions, devices, methods, and steps in the specific embodiments described in the specification. Any person with ordinary skill in the art may understand the current or future development processes, machines, manufactures, material compositions, devices, methods, and steps from the content of the disclosure, which may all be adopted according to the disclosure as long as they may implement substantially the same function or obtain substantially the same result in an embodiment described here. Therefore, the scope of the disclosure includes the above manufacturing processes, machines, manufactures, material compositions, devices, methods, and steps. In addition, each claim constitutes an individual embodiment, and the scope of the disclosure also includes the combination of each claim and embodiment. The scope of the disclosure shall be subject to the scope defined by the following claims.

What is claimed is:

1. An electronic device, comprising:
at least one first electronic unit;
an encapsulating layer surrounding the at least one first electronic unit;
a circuit structure electrically connected to the at least one first electronic unit;
a conductor layer, wherein the circuit structure and the conductor layer are corresponded to opposite sides of the encapsulating layer; and
a connection element disposed between the circuit structure and the conductor layer, wherein the encapsulating layer surrounds the connection element and comprises a recess.

2. The electronic device according to claim 1, further comprising:
an adhesive layer disposed between the encapsulating layer and the conductor layer.

3. The electronic device according to claim 1, wherein the connection element comprises a silicon bulk, a metal bulk, or a bulk with a composite material.

4. The electronic device according to claim 1, wherein the circuit structure is electrically connected to the conductor layer through the connection element.

5. The electronic device according to claim 1, wherein a thermal conductivity of the connection element is the same as or different from a thermal conductivity of the conductor layer.

6. The electronic device according to claim 1, wherein the circuit structure comprises at least one conductor structure, and the at least one conductor structure comprises another recess overlapping with the connection element.

7. The electronic device according to claim 1, further comprising a printed circuit board and a plurality of contact elements, wherein a package structure comprising the at least one first electronic unit and the encapsulating layer is electrically connected to the printed circuit board through the plurality of contact elements.

8. The electronic device according to claim 7, further comprising an underfill disposed between the printed circuit board and the package structure, wherein a portion of the underfill contacts a portion of the encapsulating layer where the recess is formed.

9. The electronic device according to claim 7, further comprising an electronic element disposed on the printed circuit board, wherein the electronic element is electrically connected to the package structure through the printed circuit board.

10. The electronic device according to claim 1, wherein a surface of the encapsulating layer facing the conductor layer and a surface of the at least one first electronic unit facing the conductor layer have a gap of 1 μm to 10 μm.

11. The electronic device according to claim 1, wherein the encapsulating layer comprises a first side and a second side where the recess is formed respectively and opposite to each other in a horizontal direction, the first side and the second side are spaced apart by a width W1 in the horizontal direction, a maximum width of the recess at the first side in the horizontal direction is W2, a maximum width of the recess at the second side in the horizontal direction is W3, and
$$( W 2 + W 3 ) * 100 \% \leq 25 \% .$$

12. The electronic device according to claim 1, wherein the encapsulating layer comprises a first side and a second side where the recess is formed respectively and opposite to each other in a horizontal direction, and one of the first side and the second side is at an angle of less than 45 degrees to a sidewall of the at least one first electronic unit facing the one of the first side and the second side.

13. The electronic device according to claim 1, wherein a level height of a bottom surface of the recess is higher than a level height of a top surface of an electronic element comprised in the at least one first electronic unit.

14. The electronic device according to claim 1, wherein a sidewall of the encapsulating layer where the recess is formed comprises a first surface defining the recess and a second surface below the recess, and a surface roughness of the first surface is different from a surface roughness of the second surface.

15. The electronic device according to claim 14, wherein the first surface comprises a curved surface.

16. The electronic device according to claim 1, wherein the circuit structure comprises at least one conductor structure, and the at least one conductor structure comprises a first conductive layer disposed on the encapsulating layer and electrically connected to the connection element, wherein a portion of the first conductive layer extends into the recess.

17. The electronic device according to claim 16, wherein the at least one conductor structure further comprises a second conductive layer disposed on the first conductive layer, wherein a portion of the second conductive layer extends into the recess and positioned on the portion of the first conductive layer.

18. The electronic device according to claim 1, wherein the connection element comprises a conductive element and an insulation layer surrounding the conductive element.

19. The electronic device according to claim 1, further comprising:
an underfill surrounding the encapsulating layer and comprising a portion in contact with a portion of the encapsulating layer.

20. A method of manufacturing an electronic device, comprising:
providing at least one electronic unit;
providing an encapsulating layer surrounding the at least one electronic unit;
providing a circuit structure electrically connected to the at least one electronic unit;
providing a conductor layer, wherein the circuit structure and the conductor layer are corresponded to opposite sides of the encapsulating layer;
providing a connection element disposed between the circuit structure and the conductor layer; and
forming a recess in the encapsulating layer, wherein the recess is formed between neighboring two of the at least one electronic unit.
